(19) United States
(12) Patent Application Publication
(10) Pub. No.: US 2025/0008664 A1
(43) Pub. Date: Jan. 2, 2025

(54) METHOD FOR ESTABLISHING AN ELECTRICAL CONNECTION AND/OR COMMUNICATION LINK

(71) Applicant: SIEMENS AKTIENGESELLSCHAFT, München (DE)

(72) Inventor: Jens JÄHNICKE, Chemnitz (DE)

(73) Assignee: SIEMENS AKTIENGESELLSCHAFT, 80333 München (DE)

(21) Appl. No.: 18/694,758

(22) PCT Filed: Aug. 5, 2022
(86) PCT No.: PCT/EP2022/072073

§ 371 Date: Mar. 22, 2024

(30) Foreign Application Priority Data
Sep. 23, 2021 (EP) 21198605.4

(51) Int. Cl. H05K 3/12; H05K 1/02

(52) U.S. Cl. CPC H05K 3/1241; H05K 1/0254; H05K 2201/0999; H05K 2203/0126

(57) ABSTRACT

In a method for producing an electrical and/or communication connection between at least two components arranged in a switchgear cabinet for transferring electrical energy or for transporting data, an electrically conductive material is applied to a back wall of the switchgear cabinet. The electrically conductive material includes metal and is applied to the back wall in the form of a wire. While being applied to the back wall of the switchgear cabinet, the electrically conductive material is warmed or heated in such a way as to become liquid during application.

In industrial plants and machines, electrical devices and components are usually gathered together in switchgear cabinets. The devices and components are electrically or communicatively connected by means of cables.

From US2021/0176885A1 a back wall circuit board for electrically connecting electrical components and a method for producing the back wall circuit board are known. The back wall comprises an assembly plate, conductor tracks arranged on the assembly plate, which are arranged on the support plate, and at least one sensor unit. The method comprises integrating the at least one sensor unit in the assembly plate by way of an additive production method (“3D printing”) and printing the conductor tracks from an electrically conductive paste.

From US2017/0228060A1 a user interface for a device is known which comprises a control panel and a control component secured to the control panel. The user interface display panel comprises a large number of conductor tracks for establishing an electrical connection for the control component. The plurality of conductor tracks are integrally embodied with the user interface display panel such that the plurality of conductor tracks and the user interface display panel form a single, coherent component part. The conductor tracks and the user interface display panel can be integrally formed in an additive manufacturing method.

Interconnecting of this kind can only be established manually, however.

This is very cost-intensive.

The invention is based on the object of improving this.

The object is achieved by claim 1, that is to say a method for producing an electrical and/or communication connection between at least two components arranged in a switchgear cabinet for transferring electrical energy or for transporting data, wherein the electrical and/or communication connection is created by applying a material to a back wall of the switchgear cabinet, wherein the material is an electrically conductive material and is available in the form of a wire and during application is warmed or heated in such a way that it is liquid during application.

The material is advantageously liquid or semi-liquid or viscous, but not solid, during application.

Advantageously, the material was warmed to achieve a desired viscosity. The material is advantageously viscous in such a way that when it is applied it does not flow away unimpeded and instead tracks can be formed.

The connection can thus be produced flexibly and inexpensively.

The connection and the back wall are preferably connected by way of a material bond.

An embodiment according to which the material is applied preferably by means of Fused Deposition Modeling or Fused Filament Fabrication is advantageous.

The Fused Deposition Modeling (FDM) or Fused Filament Fabrication (FFF) 3D printing methods are manufacturing methods in which a workpiece is built up, for example in layers, from a fusible plastics material or also from molten metal.

Within the meaning of the invention, electrical and/or communication connections are created on the back wall of the switchgear cabinet by means of the method.

The methods are additive manufacturing methods which are suitable owing to their cost effectiveness.

An embodiment according to which the material is applied in such a way that tracks are formed is advantageous.

Reference can be made within the context of this invention to printed conductor tracks.

This makes optimum transporting of energy and/or data possible.

An embodiment according to which the material has at least one electrically conductive material portion is advantageous.

Preferably, the electrically conductive material portion is at least 90%.

An embodiment according to which the material has a metal is advantageous.

The material is preferably available in the form of a wire and is warmed or heated during application in such a way that it is liquid and application to the back wall turns out well.

A thin-liquid or viscous form is also conceivable.

An embodiment according to which the material has tin solder and/or aluminum and/or copper is advantageous.

These materials are well suited for transferring electrical energy and data.

An embodiment according to which the material has glass is advantageous.

In this connection, the material is heated in such a way that a glass fiber is directly applied to the back wall. This is very advantageous with regard to data transfer.

An embodiment according to which the material is applied in one layer is advantageous.

This is particularly time-saving.

Alternatively, the material can also be applied in a plurality of layers.

The material is advantageously applied by means of one layer or in one pass, so a desired cross-section is achieved. The application of a plurality of layers is also possible, however.

An embodiment according to which a contacting element for establishing contact with a component is formed at one end at least of the electrical and/or communication connection is advantageous.

Contacting elements can also be printed alongside. Alternatively, prefabricated elements can be used.

Advantageously, the material is fused and applied to the back wall as a liquid melt.

Direct application to the back wall can achieve good heat dissipation. A touch guard can subsequently be applied.

An embodiment according to which the material is an electrically conductive material is also advantageous.

This has the advantage that no sintering is necessary. The material can thus assume the function of a conducting track.

The object is also achieved by a back wall of a switchgear cabinet, having at least one electrical and/or communication connection for connecting at least two components, produced by the described method.

Furthermore, the object is achieved by a switchgear cabinet, having at least two components and a back wall.

The invention will be described and explained in more detail hereinafter on the basis of the exemplary embodiments represented in the figures. In the drawings:

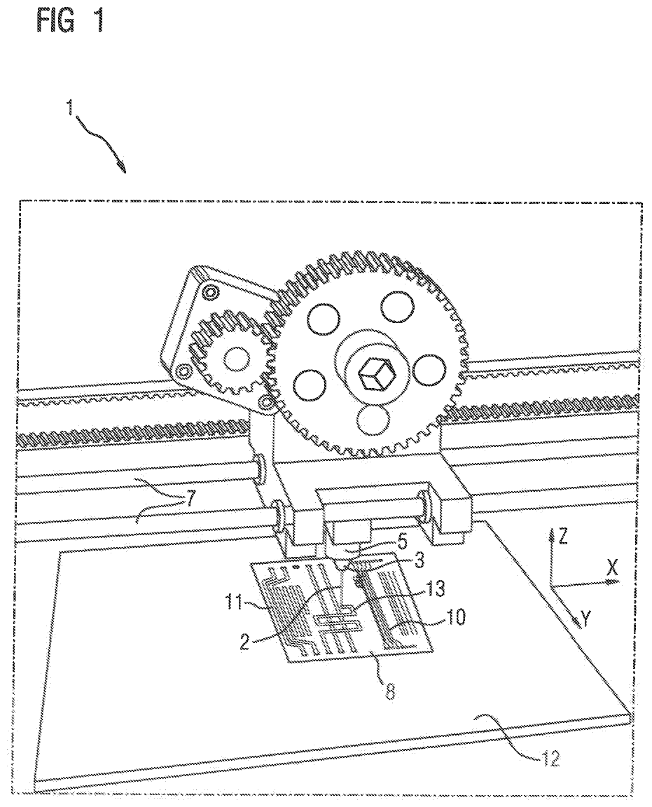

FIG. 1 shows a 3D printer during application of a material,

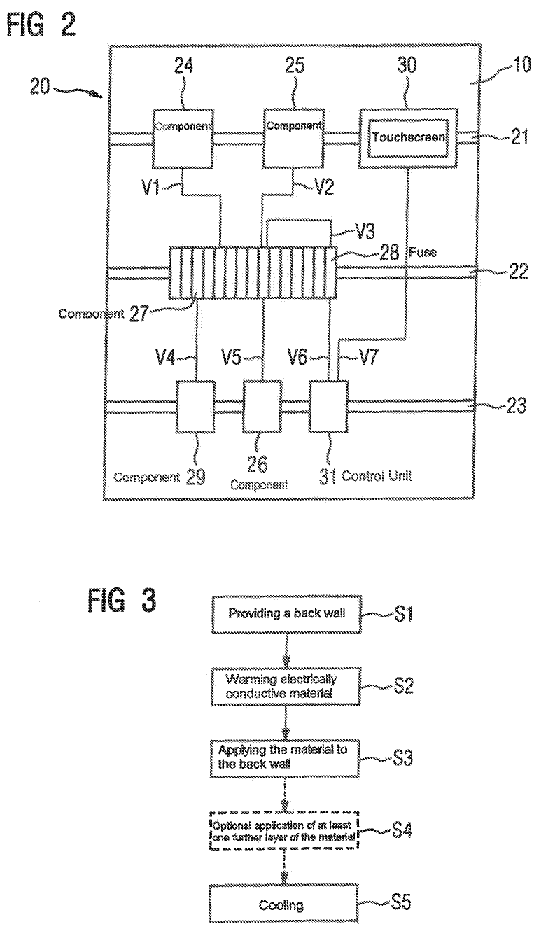

FIG. 2 shows a switchgear cabinet,

FIG. 3 shows method steps.

FIG. 1 shows a 3D printer 1 during application of a material 2.

The material is preferably a good electrical conductor and is, for example, tin solder and/or aluminum and/or copper.

The material 2 is warmed by means of a heating element 5 and applied to a back wall 10 by way of a nozzle 3. The back wall 10 is lying on a workbench 12 in the figure.

The nozzle 3 advantageously has a shaping opening. Advantageously, the material is extruded from the nozzle. Tracks 11, 13 can thus be formed.

The tracks 11, 13 are the connections V1 . . . . V7, or a part thereof, shown in FIG. 2. The connections V1 . . . . V7 can also be provided, for example, with a touch guard or an insulating layer. Advantageously, this can also, but does not have to be, applied by means of the nozzle 3 in a separate layer.

A plurality of layers of the material can be applied to achieve a desired thickness of the connection.

The figure shows three axes X, Y and Z. One travel path 7 is shown by way of example.

FIG. 2 shows a switchgear cabinet 20. The switchgear cabinet 20 has the back wall 10.

The switchgear cabinet 20 includes the racks 21, 22 and 23 on which a plurality of components 24, 25, 27, 28, 29, 30 is arranged.

The figure shows a plurality of connections V1 . . . 7 which were established by means of the described method (see FIG. 3). The connections connect components electrically and/or communicatively. Electrical energy and/or data is transported therefore. The connections can be referred to as conductor tracks.

Example: the component 25 is a power supply unit which is electrically connected to the component 28, which is a fuse. The component 28 and the component 31 are electrically connected, with the component 31 being a control unit. The component 30 is a touchscreen in this example. The component 30 and the component 31 are electrically and communicatively connected, comparably to a bus, which enables the exchange of data and energy.

Advantageously, a suitable contacting element 8 (see FIG. 1) is embodied at the respective ends of the electrical and/or communication connection for establishing contact with the respective component.

Contact is established, for example, by means of a spring contact. Advantageously, the spring contact is arranged on the component. Spring contact and component are then advantageously in one piece.

Alternatively, the spring contact can be a single component part, which is designed, for example, so it can be plugged on the component.

FIG. 3 shows method steps.

The back wall is provided in a method step S1.

The material is warmed in a method step S2.

The material S3 is applied to the back wall in a method step S3. The material is advantageously applied preferably by means of Fused Deposition Modeling or Fused Filament Fabrication.

A further layer of the material or a plurality of further layers of the material is applied in an optional method step S4.

Completion, which includes, for example, cooling of the connections created, takes place in a method step S5.

The material advantageously becomes solid or hard due to cooling.

1.-12. (canceled)

13. A method for producing an electrical and/or communication connection between at least two components arranged in a switchgear cabinet for transferring electrical energy or for transporting data, the method comprising:
applying to a back wall of the switchgear cabinet an electrically conductive material which comprises metal and is formed as a wire; and
while being applied to the back wall of the switchgear cabinet, warming or heating the electrically conductive material to become liquid during application.

14. The method of claim 13, wherein the electrically conductive material is applied by Fused Deposition Modeling or Fused Filament Fabrication.

15. The method of claim 13, wherein the electrically conductive material is applied in such a way as to form tracks.

16. The method of claim 13, wherein the electrically conductive material comprises at least one electrically conductive material portion.

17. The method of claim 13, wherein the electrically conductive material comprises tin solder and/or aluminum and/or copper.

18. The method of claim 13, wherein the electrically conductive material comprises glass.

19. The method of claim 13, wherein the electrically conductive material is applied in a layer.

20. The method of claim 13, further comprising forming a contacting element for establishing contact with a respective one of the at least two components at one end of the electrical and/or communication connection.

21. The method of claim 13, wherein the electrically conductive material is fused and applied to the back wall as a liquid melt.

22. A back wall of a switchgear cabinet, the back wall comprising an electrical and/or communication connection between at least two components arranged in the switchgear cabinet for transferring electrical energy or for transporting data, said electrical and/or communication connection formed by an electrically conductive material which comprises metal and is formed as a wire and which is applied as liquid.

23. The back wall of claim 22, wherein the electrically conductive material of the electrical and/or communication connection forms tracks.

24. The back wall of claim 22, wherein the electrically conductive material comprises at least one electrically conductive material portion.

25. The back wall of claim 22, wherein the electrically conductive material comprises tin solder and/or aluminum and/or copper.

26. The back wall of claim 22, wherein the electrically conductive material comprises glass.

27. The back wall of claim 22, wherein the electrically conductive material is applied in a layer.

28. The back wall of claim 22, further comprising a contacting element designed to establish a contact with a respective one of the at least two components at one end of the electrical and/or communication connection.

29. The back wall of claim 22, wherein the liquid is liquid melt.

30. A switchgear cabinet, comprising:
at least two components; and
a back wall comprising an electrical and/or communication connection between the at least two components for transferring electrical energy or for transporting data, said electrical and/or communication connection formed by an electrically conductive material which comprises metal and is formed as a wire and which is applied as liquid.

31. The switchgear cabinet of claim 30, wherein the electrically conductive material of the electrical and/or communication connection forms tracks on the back wall.

32. The switchgear cabinet of claim 31, wherein the back wall comprises a contacting element designed to establish a contact with a respective one of the at least two components at one end of the electrical and/or communication connection.
